(19) United States
(12) Patent Application Publication
(10) Pub. No.: US 2026/0005662 A1
(43) Pub. Date: Jan. 1, 2026

(54) SEMICONDUCTOR DEVICE HAVING DIFFERENTIAL AMPLIFIER

(71) Applicant: MICRON TECHNOLOGY, INC., Boise, ID (US)

(72) Inventor: Shuichi Tsukada, Sagamihara (JP)

(73) Assignee: MICRON TECHNOLOGY, INC., Boise, ID (US)

(21) Appl. No.: 19/247,292

(22) Filed: Jun. 24, 2025

Related U.S. Application Data
(60) Provisional application No. 63/665,103, filed on Jun. 27, 2024.

(51) Int. Cl. H03F 3/45

(52) U.S. Cl. CPC H03F 3/45273; H03F 3/45183

(57) ABSTRACT

An example apparatus includes: a first current path between first and second voltages, the first current path including a first transistor coupled to the first voltage, second and third transistors coupled in parallel between the first transistor and the second voltage, gates of the second and third transistor configured to receive a first signal, commonly; and a second current path between the first and second voltages, the second current path including a fourth transistor of which a gate is coupled to a gate of the first transistor, fifth and sixth transistors coupled in parallel between the fourth transistor and the second voltage, gates of the fifth and sixth transistors configured to receive a second signal, commonly. Each of the second and fifth transistors has a different threshold voltage than each of the third and sixth transistors.

### CROSS-REFERENCE TO RELATED APPLICATIONS

This application claims the filing benefit of U.S. Provisional Application No. 63/665,103, filed Jun. 27, 2024. This application is incorporated by reference herein in its entirety and for all purposes.

### BACKGROUND

A semiconductor device includes a differential amplifier in some cases. FIG. 8 is a circuit diagram of a general differential amplifier. The differential amplifier shown in FIG. 8 includes P-channel MOS transistors M1 and M2 constituting a current mirror circuit, an N-channel MOS transistor M3 coupled in series to the transistor M1, an N-channel MOS transistor M4 coupled in series to the transistor M2, N-channel MOS transistors M5 and M6 constituting a current mirror circuit, and a resistor R1. A common source of the transistors M3 and M4 is coupled to the transistor M5 constituting a current source. An input signal IN is supplied to a gate electrode of the transistor M3. The connection point between the transistor M2 and the transistor M4 is an output node N3. An output signal OUT appearing at the output node N3 is fed back to a gate electrode of the transistor M4. With this configuration, the differential amplifier shown in FIG. 8 performs as a voltage follower circuit.

FIGS. 9A and 9B are operation waveform diagrams of the differential amplifier shown in FIG. 8. FIG. 9A shows relations among the voltage level of the input signal IN, the voltage levels of nodes N1 and N2, and the voltage level of the output signal OUT. FIG. 9B shows a relation between the voltage level of the input signal IN and an operation current I(M5) flowing into the transistor M5. As shown in FIG. 9B, when the voltage level of the input signal IN exceeds a voltage V1, the operation current I(M5) flows into the transistor M5, so that the differential amplifier shown in FIG. 8 is operated normally. In this case, the voltage level of the output signal OUT matches the voltage level of the input signal IN. However, when the voltage level of the input signal IN is equal to or less than the voltage V1, the operation current I(M5) does not flow into the transistor M5, so that operation of the differential amplifier shown in FIG. 8 is stopped.

### BRIEF DESCRIPTION OF THE DRAWINGS

FIG. 1 is a circuit diagram of a differential amplifier according to a first embodiment of the present disclosure;

FIGS. 2A and 2B are operation waveform diagrams of the differential amplifier shown in FIG. 1;

FIG. 3A is a circuit diagram of a differential amplifier according to a second embodiment of the present disclosure;

FIG. 3B is a circuit diagram of a differential amplifier according to a modification of the second embodiment;

FIG. 4 is a circuit diagram of a differential amplifier according to a third embodiment of the present disclosure;

FIG. 5 is a circuit diagram of a voltage regulator circuit according to a fourth embodiment of the present disclosure;

FIGS. 6A and 6B are operation waveform diagrams of the voltage regulator circuit shown in FIG. 5;

FIG. 7 is a circuit diagram of a voltage regulator circuit according to a fifth embodiment of the present disclosure;

FIG. 8 is a circuit diagram of a general differential amplifier; and

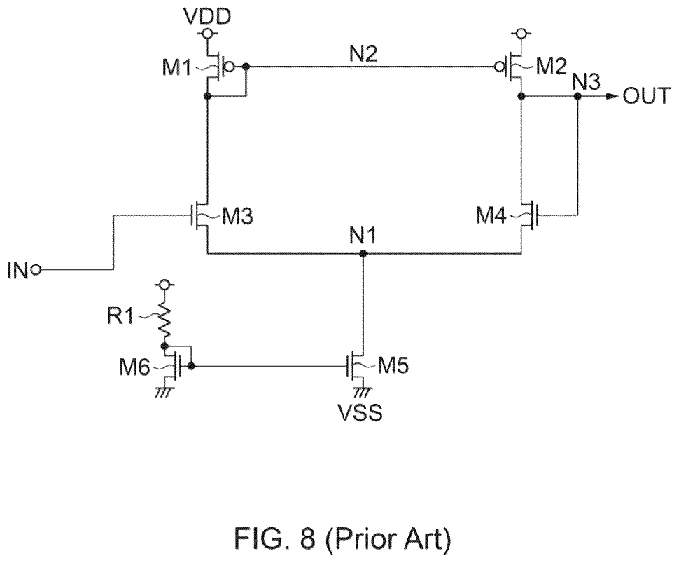

FIGS. 9A and 9B are operation waveform diagrams of the differential amplifier shown in FIG. 8.

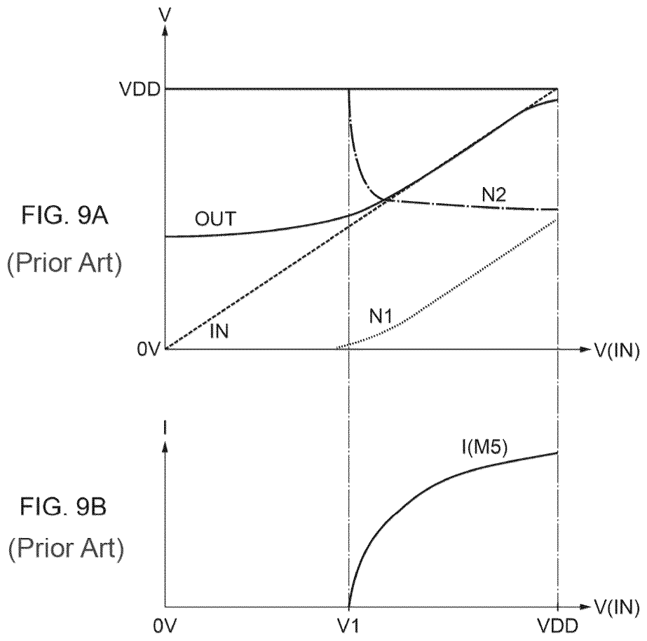

### DETAILED DESCRIPTION

Various embodiments of the present disclosure will be explained below in detail with reference to the accompanying drawings. The following detailed description refers to the accompanying drawings that show, by way of illustration, specific aspects, and various embodiments of the present disclosure. The detailed description provides sufficient detail to enable those skilled in the art to practice these embodiments of the present disclosure. Other embodiments may be utilized, and structural, logical, and electrical changes may be made without departing from the scope of the present disclosure. The various embodiments disclosed herein are not necessarily mutually exclusive, as some disclosed embodiments can be combined with one or more other disclosed embodiments to form new embodiments.

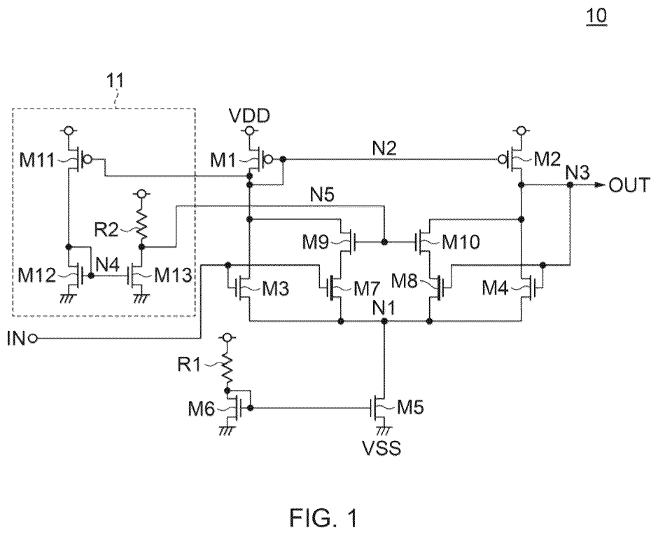

FIG. 1 is a circuit diagram of a differential amplifier 10 according to a first embodiment of the present disclosure. The differential amplifier 10 shown in FIG. 1 performs as a voltage follower circuit. The differential amplifier 10 includes P-channel MOS transistors M1 and M2 constituting a current mirror circuit, an N-channel MOS transistor M3 coupled in series to the transistor M1, an N-channel MOS transistor M4 coupled in series to the transistor M2, N-channel MOS transistors M9 and M7 coupled in series to the transistor M1, N-channel MOS transistors M10 and M8 coupled in series to the transistor M2, N-channel MOS transistors M5 and M6 constituting a current mirror circuit, a resistor R1, and a bias detector 11. The transistor M3 and the transistors M9 and M7 are coupled in parallel between the transistor M1 and a node N1. The transistor M4 and the transistors M10 and M8 are coupled in parallel between the transistor M2 and the node N1.

The transistors M3 and M4 constitute a pair of input transistors. The transistors M7 and M8 constitute another pair of input transistors. The threshold voltage of each of the transistors M7 and M8 is lower than the threshold voltage of each of the transistors M3 and M4.

The node N1 as a common source of the transistors M3, M4, M7, and M8 is coupled to the transistor M5. Among currents flowing into the transistor M5, a current flowing through the transistors M3, M7, and M9 is supplied via the transistor M1 constituting an input transistor of a current mirror circuit. Among currents flowing into the node N1, a current flowing through the transistors M4, M8, and M10 is supplied via the transistor M2 constituting an output transistor of a current mirror circuit. The sizes of the transistor M1 and the transistor M2 are mutually the same. Therefore, mutually the same amount of current flows into the transistor M1 and the transistor M2.

An input signal IN is commonly supplied to gate electrodes of the transistors M3 and M7. The connection point between the transistor M2 and the transistor M4 is the output node N3. An output signal OUT appearing at the output node N3 is commonly fed back to gate electrodes of the transistors M4 and M8. A control signal N5 is commonly supplied to gate electrodes of the transistors M9 and M10. The control signal N5 is generated by the bias detector 11.

The bias detector 11 includes a P-channel MOS transistor M11, N-channel MOS transistors M12 and M13, and a resistor R2. A gate electrode of the transistor M11 is coupled to a node N2. Accordingly, the transistor M11 constitutes another output transistor of a current mirror circuit having the transistor M1 as its input transistor. The transistors M12 and M13 constitute a current mirror circuit. The transistor M12 as an input transistor of the current mirror circuit is coupled in series to the transistor M11. The transistor M13 as an output transistor of the current mirror circuit is coupled in series to the resistor R2. The control signal N5 appears at the connection point between the transistor M13 and the resistor R2.

Since the transistor M1 and the transistor M11 constitute a current mirror circuit, the amount of current flowing into the transistor M11 is proportional to the amount of current flowing into the transistor M1. The current flowing into the transistor M11 is caused to flow into the resistor R2 by a current mirror circuit formed of the transistors M12 and M13. Accordingly, the current flowing into the resistor R2 is proportional to an operation current I(M5) flowing into the transistor M5.

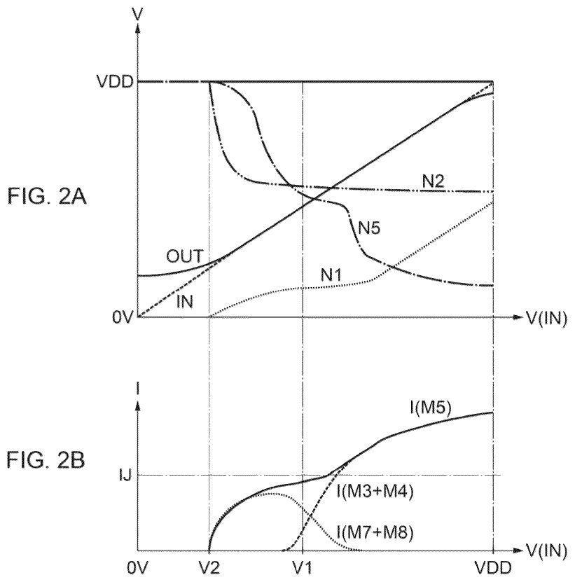

FIGS. 2A and 2B are operation waveform diagrams of the differential amplifier 10 shown in FIG. 1. FIG. 2A shows relations among the voltage level of the input signal IN, the voltage levels of the nodes N1 and N2, the voltage level of the control signal N5, and the voltage level of the output signal OUT. FIG. 2B shows a relation between the voltage level of the input signal IN and the operation current I(M5) flowing into the transistor M5. As shown in FIG. 2A, when the voltage level of the input signal IN is close to the level of a power supply potential VDD, the voltage level of the control signal N5 is low and is equal to or less than threshold voltages of the transistors M9 and M10. This is because, as the amount of current flowing into the resistor R2 is large, voltage drop due to the resistor R2 is large. In this state, since the transistors M9 and M10 are turned off, all of the operation current I(M5) passes through the transistors M3 and M4. That is, I(M5)=I(M3+M4) is established. Further, when the threshold voltage of each of the transistors M3 and M4 is set to be VTN(M3), the voltage of the node N1 is substantially IN−VTN(M3). When the threshold voltage of each of the transistors M1 and M2 is set to be VTP(M1), the voltage of the node N2 is substantially VDD−VTP(M1). Here, in order to operate the differential amplifier 10, the voltage level of the node N2 needs to be higher than the voltage level of the node N1. Therefore, in order to maintain N2>N1 even when V(IN)=VDD is established, VTN(M3) needs to be larger than VTP(M1). In order to satisfy this condition, the threshold voltage VTN(M3) of each of the transistors M3 and M4 is designed to be relatively high.

When the voltage level of the input signal IN is gradually decreased from the level of the power supply potential VDD, the voltage level of the node N1 is decreased and a source-drain voltage VDS of the transistor M5 becomes less, so that the operation current I(M5) is gradually decreased and the amount of current flowing into the resistor R2 is also gradually decreased. As a result, the voltage level of the control signal N5 gradually rises. Subsequently, the voltage level of the input signal IN becomes equal to or less than a voltage V1, and when the operation current I(M5) becomes less than an amount of current IJ shown in FIG. 2B as a consequence, the voltage level of the control signal N5 exceeds the threshold voltages of the transistors M9 and M10 and the transistors M9 and M10 are turned on. The voltage V1 is substantially equal to the threshold voltages of the transistors M3 and M4. When the transistors M9 and M10 are turned on, the transistors M3 and M4 are turned off, and thus all of the operation current I(M5) passes through the transistors M7 and M8. That is, I(M5)=I(M7+M8) is established. Further, when the voltage level of the input signal IN becomes equal to or less than a voltage V2 that is the threshold voltage of each of the transistors M7 and M8, the transistors M7 and M8 are turned off and the operation current I(M5) becomes substantially zero.

As described above, in the differential amplifier 10 shown in FIG. 1, when the voltage level of the input signal IN is within V1 to VDD, the transistors M3 and M4 each having a high threshold voltage perform as a pair of input transistors, and when the voltage level of the input signal IN is within V2 to V1, the transistors M7 and M8 each having a low threshold voltage perform as a pair of input transistors. Accordingly, the range of voltage within which the input signal IN can be input can be increased more as compared to conventional technologies. Further, when the voltage level of the input signal IN exceeds the voltage V1, the path passing through the transistors M7 and M8 each having a low threshold voltage is blocked by the transistors M9 and M10, so that the voltage level of the node N1 never becomes higher than the voltage level of the node N2. Furthermore, the amount of current IJ can be adjusted according to the resistance ratio between the resistor R1 and the resistor R2, the size ratio between the transistor M1 and the transistor M11, and the size ratio between the transistor M12 and the transistor M13.

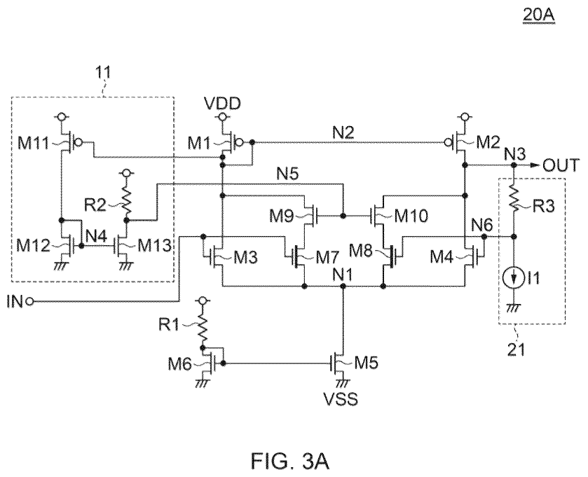

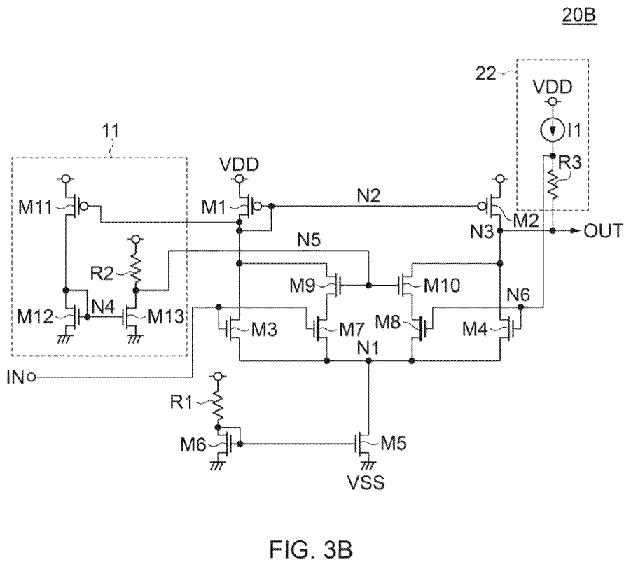

FIG. 3A is a circuit diagram of a differential amplifier 20A according to a second embodiment of the present disclosure. The differential amplifier 20A shown in FIG. 3A is different from the differential amplifier 10 according to the first embodiment in a feature that a feedback circuit 21 is added to the differential amplifier 20A. The feedback circuit 21 includes the output node N3 from which the output signal OUT is output and a resistor R3 and a constant-current source I1 that are coupled in series between power supply lines to which a ground potential VSS is supplied. A potential appearing at a node N6 as the connection point between the resistor R3 and the constant-current source I1 is supplied to the gate electrodes of the transistors M4 and M8. With this configuration, the voltage level of the output signal OUT becomes a level obtained by adding a voltage drop (=R3×I1) of the resistor R3 to the voltage level of the input signal IN. A MOS transistor and a resistor may be used instead of the resistor R3 and the constant-current source I1.

FIG. 3B is a circuit diagram of a differential amplifier 20B according to a modification of the second embodiment. The differential amplifier 20B shown in FIG. 3B is different from the differential amplifier 10 according to the first embodiment in a feature that a feedback circuit 22 is added to the differential amplifier 20B. The feedback circuit 22 includes the output node N3 from which the output signal OUT is output and the constant-current source I1 and the resistor R3 that are coupled in series between power supply lines to which the ground potential VDD is supplied. A potential appearing at the node N6 as the connection point between the resistor R3 and the constant-current source I1 is supplied to the gate electrodes of the transistors M4 and M8. With this configuration, the voltage level of the output signal OUT becomes a level obtained by subtracting a voltage drop (=R3×I1) of the resistor R3 from the voltage level of the input signal IN.

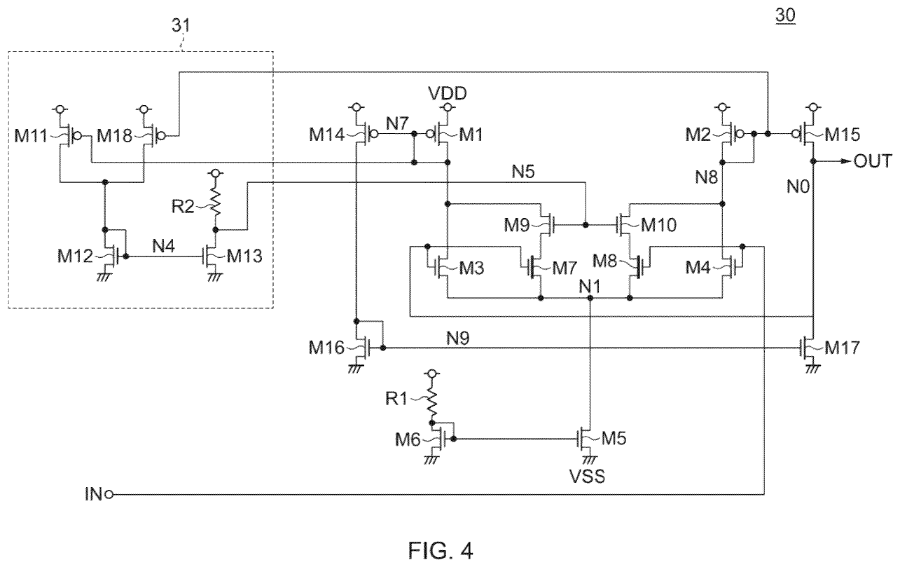

FIG. 4 is a circuit diagram of a differential amplifier 30 according to a third embodiment of the present disclosure. The differential amplifier 30 shown in FIG. 4 is different from the differential amplifier 10 according to the first embodiment in a feature that P-channel MOS transistors M14 and M15 and N-channel MOS transistors M16 and M17 are added to the differential amplifier 30 and a feature that the bias detector 11 is replaced with a bias detector 31. In the present embodiment, the input signal IN is supplied to the gate electrodes of the transistors M4 and M8 and the output signal OUT is fed back to the gate electrodes of the transistors M3 and M7.

The transistor M1 and the transistor M14 constitute a current mirror circuit in which the transistor M1 is its input side and the transistor M14 is its output side. The transistor M2 and the transistor M15 constitute a current mirror circuit in which the transistor M2 is its input side and the transistor M15 is its output side. The transistor M16 and the transistor M17 constitute a current mirror circuit in which the transistor M16 is its input side and the transistor M17 is its output side. The transistor M14 and the transistor M16 are coupled to each other in series. The transistor M15 and the transistor M17 are coupled to each other in series. The output signal OUT is output from a connection point NO between the transistor M15 and the transistor M17. With this push-pull circuit configuration, the amplitude of the output signal OUT can be increased more as compared to that generated by the differential amplifier 10 shown in FIG. 1.

The bias detector 31 is different from the bias detector 11 shown in FIG. 1 in a feature that a P-channel MOS transistor M18 is added to the bias detector 31. Gate electrodes of the transistors M11 and M18 are respectively coupled to nodes N7 and N8. Accordingly, the transistor M11 constitutes another output transistor of a current mirror circuit in which the transistor M1 is its input transistor, and the transistor M18 constitutes another output transistor of a current mirror circuit in which the transistor M2 is its input transistor. As a result, the current flowing into the transistor M11 is proportional to the current flowing into the transistor M1 and the current flowing into the transistor M18 is proportional to the current flowing into the transistor M2. The transistor M11 and the transistor M18 are coupled to each other in parallel. As a result, the current flowing into the resistor R2 is proportional to the operation current I(M5) flowing into the transistor M5.

As described above, the technology according to the present disclosure can be also applied to push-pull differential amplifiers.

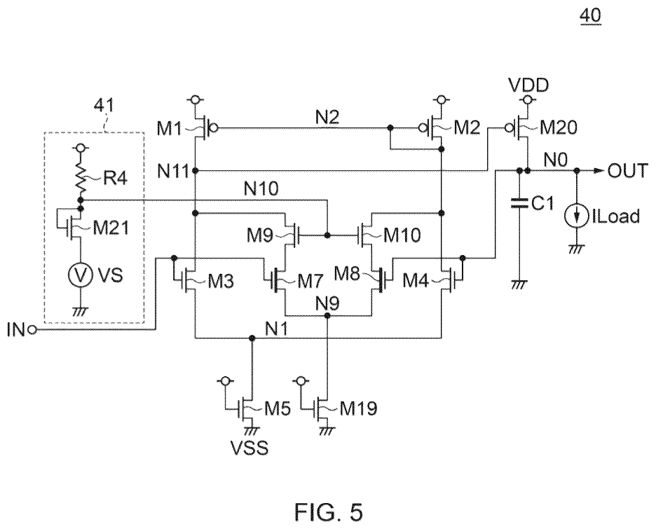

FIG. 5 is a circuit diagram of a voltage regulator circuit 40 according to a fourth embodiment of the present disclosure. The voltage regulator circuit 40 shown in FIG. 5 includes the P-channel MOS transistors M1 and M2 constituting a current mirror circuit, the N-channel MOS transistor M3 coupled in series to the transistor M1, the N-channel MOS transistor M4 coupled in series to the transistor M2, the N-channel MOS transistors M9 and M7 coupled in series to the transistor M1, the N-channel MOS transistors M10 and M8 coupled in series to the transistor M2, the N-channel MOS transistor M5 and an N-channel MOS transistor M19 constituting a current source circuit, a P-channel MOS transistor M20 constituting a driver circuit, a decoupling capacitor C1, and a voltage generator 41. In the present embodiment, the transistor M1 constitutes an output transistor of the current mirror circuit and the transistor M2 constitutes an input transistor of the current mirror circuit.

The transistors M3 and M4 constitute a pair of input transistors. The transistors M7 and M8 constitute another pair of input transistors. The threshold voltage of each of the transistors M7 and M8 is lower than the threshold voltage of each of the transistors M3 and M4. The node N1 as a common source of the transistors M3 and M4 is coupled to the transistor M5. A node N9 as a common source of the transistors M7 and M8 is coupled to the transistor M19. In this manner, in the voltage regulator circuit 40 shown in FIG. 5, since the common source of the transistors M3 and M4 and the common source of the transistors M7 and M8 are separated from each other, the node N1 and the node N9 may have a mutually different voltage level.

The input signal IN is commonly supplied to the gate electrodes of the transistors M3 and M7. Anode N11 as the connection point between the transistor M1 and the transistor M3 is coupled to a gate electrode of the transistor M20 constituting a driver circuit. An output node NO as a drain of the transistor M20 is coupled to a load circuit and is commonly fed back to the gate electrodes of the transistors M4 and M8. While a current ILoad flowing into the load circuit changes according to various conditions such as its operation mode and temperature, an output voltage OUT of the output node NO is kept constant. Further, the decoupling capacitor C1 coupled in parallel to the load circuit compensates the phase of the output voltage OUT.

A control signal N10 is commonly supplied to the gate electrodes of the transistors M9 and M10. The control signal N10 is generated by the voltage generator 41. The voltage generator 41 is formed of a resistor R4, a diode-coupled N-channel MOS transistor M21, and a series circuit of a voltage source VS. The control signal N10 appears at the connection point between the resistor R4 and the transistor M21. Accordingly, the control signal N10 is fixed at a constant voltage level. When the threshold voltage of the transistor M21 is set to be VTN(M21), the voltage level of the control signal N10 is expressed as VS+VTN(M21).

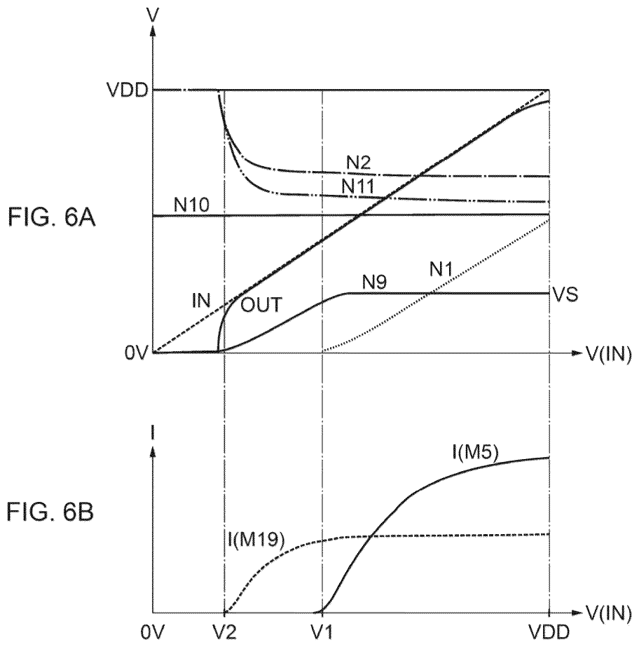

FIGS. 6A and 6B are operation waveform diagrams of the voltage regulator circuit 40 shown in FIG. 5. FIG. 6A shows relations among the voltage level of the input signal IN, the voltage levels of the nodes N1, N2, and N9 to N11, and the voltage level of the output voltage OUT. FIG. 6B shows relations among the voltage level of the input signal IN, the operation current I(M5) flowing into the transistor M5, and an operation current I(M19) flowing into the transistor M19. As shown in FIG. 6A, when the voltage level of the input signal IN exceeds the voltage V2 as the threshold voltage of each of the transistors M7 and M8, the transistors M7 and M8 are turned on and the voltage level of the node N9 rises. Further, when the voltage level of the input signal IN exceeds the voltage V1 as the threshold voltage of each of the transistors M3 and M4, the transistors M3 and M4 are turned on and the voltage level of the node N1 rises. Note that since the transistors M9 and M10 having the control signal N10 supplied to the gate electrodes thereof are respectively coupled in series to the transistors M7 and M8, when a threshold voltage VTN of each of the transistors M9 and M10 and a threshold voltage VTN of the transistor M21 are substantially the same, the voltage level of the node N9 is limited to the output level of the voltage source VS. Therefore, the voltage level of the node N9 never exceeds the voltage level of the node N2.

That is, in the voltage regulator circuit 40, when the voltage level of the input signal IN is within V1 to VDD, both the transistors M3 and M4 each having a high threshold voltage and the transistors M7 and M8 each having a low threshold voltage perform as input transistors, and when the voltage level of the input signal IN is within V2 to V1, the transistors M7 and M8 each having a low threshold voltage perform as a pair of input transistors. Accordingly, the range of voltage within which the input signal IN can be input can be increased more as compared to conventional technologies.

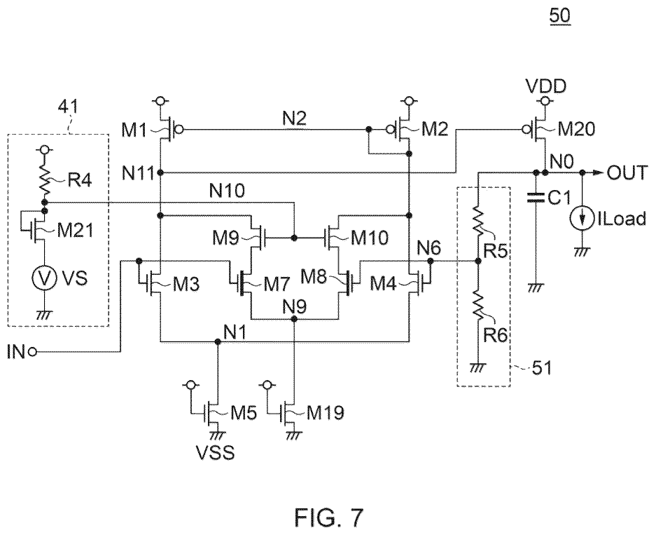

FIG. 7 is a circuit diagram of a voltage regulator circuit 50 according to a fifth embodiment of the present disclosure. The voltage regulator circuit 50 shown in FIG. 7 is different from the voltage regulator circuit 40 according to the fourth embodiment in a feature that a feedback circuit 51 is added to the voltage regulator circuit 50. The feedback circuit 51 includes the output node NO from which the output voltage OUT is output and a resistor R5 and a resistor R6 that are coupled in series between power supply lines to which the ground potential VSS is supplied. A potential appearing at the node N6 as the connection point between the resistor R5 and the resistor R6 is supplied to the gate electrodes of the transistors M4 and M8. With this configuration, it is possible to feed back a voltage level obtained by resistive-dividing the output voltage OUT with the resistors R5 and R6 to a differential amplifier.

Although various embodiments have been disclosed in the context of certain preferred embodiments and examples, it will be understood by those skilled in the art that the scope of the present disclosure extends beyond the specifically disclosed embodiments to other alternative embodiments and/or uses of the embodiments and obvious modifications and equivalents thereof. In addition, other modifications which are within the scope of this disclosure will be readily apparent to those of skill in the art based on this disclosure. It is also contemplated that various combination or sub-combination of the specific features and aspects of the embodiments may be made and still fall within the scope of the disclosure. It should be understood that various features and aspects of the disclosed embodiments can be combined with or substituted for one another in order to form varying modes of the disclosed embodiments. Thus, it is intended that the scope of at least some of the present disclosure should not be limited by the particular disclosed embodiments described above.

1. An apparatus comprising:
a first current path between first and second voltages, the first current path including a first transistor coupled to the first voltage, second and third transistors coupled in parallel between the first transistor and the second voltage, gates of the second and third transistor configured to receive a first signal, commonly; and
a second current path between the first and second voltages, the second current path including a fourth transistor of which a gate is coupled to a gate of the first transistor, fifth and sixth transistors coupled in parallel between the fourth transistor and the second voltage, gates of the fifth and sixth transistors configured to receive a second signal, commonly,
wherein each of the second and fifth transistors has a different threshold voltage than each of the third and sixth transistors.

2. The apparatus of claim 1, further comprising:
a seventh transistor coupled between the first transistor and the third transistor; and
an eighth transistor coupled between the fourth transistor and the sixth transistor,
wherein the seventh and eighth transistors are configured to be commonly controlled by a third signal.

3. The apparatus of claim 2, wherein each of the third and sixth transistors has a lower threshold voltage than each of the second and fifth transistors.

4. The apparatus of claim 3, further comprising a ninth transistor,
wherein the second and third transistors are coupled in parallel between the first transistor and the ninth transistor, and
wherein the fifth and sixth transistors are coupled in parallel between the fourth transistor and the ninth transistor.

5. The apparatus of claim 4, further comprising a bias detector configured to generate the third signal based on an amount of current flowing through the ninth transistor.

6. The apparatus of claim 5, wherein the first and fourth transistors are configured to perform as a first current mirror circuit such that one of the first and fourth transistors is configured to perform as an input transistor and that another of the first and fourth transistors is configured to perform as a first output transistor.

7. The apparatus of claim 6,
wherein the bias detector includes:
a tenth transistor configured to perform as a second output transistor of the first current mirror circuit; and
a second current mirror circuit having an input transistor coupled in series to the tenth transistor and an output transistor; and
a first resistor coupled in series to the output transistor of the second current mirror circuit, and
wherein the third signal appears between the first resistor and the output transistor of the second current mirror circuit.

8. The apparatus of claim 4, wherein an output signal appears at an output node between the fourth transistor and the fifth transistor.

9. The apparatus of claim 8, wherein the output signal is fed back to the fifth and sixth transistors as the second signal.

10. The apparatus of claim 8, further comprising a second resistor and a first current source coupled in series to the output node,
wherein the second signal appears between the second resistor and the first current source.

11. The apparatus of claim 5, further comprising:
an eleventh transistor, wherein the first and eleventh transistors are configured to perform as a first current mirror circuit such that the first transistor is configured to perform as an input transistor and the eleventh transistor is configured to perform as a first output transistor;
a twelfth transistor, wherein the fourth and twelfth transistors are configured to perform as a second current mirror circuit such that the fourth transistor is configured to perform as an input transistor and the twelfth transistor is configured to perform as a first output transistor; and
thirteenth and fourteenth transistors configured to perform as a third current mirror circuit such that the thirteenth transistor is configured to perform as an input transistor and the fourteenth transistor is configured to perform as an output transistor,
wherein the eleventh transistor and the thirteenth transistor are coupled in series,
wherein the twelfth transistor and the fourteenth transistor are coupled in series, and
wherein an output signal appears at an output node between the twelfth transistor and the fourteenth transistor.

12. The apparatus of claim 11,
wherein the bias detector includes:
a fifteenth transistor configured to perform as a second output transistor of the first current mirror circuit;
a sixteenth transistor configured to perform as a second output transistor of the second current mirror circuit;
a fourth current mirror circuit having an input transistor coupled in common to the fifteenth and sixteenth transistors and an output transistor; and
a first resistor coupled in series to the output transistor of the fourth current mirror circuit, and
wherein the third signal appears between the first resistor and the output transistor of the fourth current mirror circuit.

13. The apparatus of claim 3, further comprising ninth and tenth transistors,
wherein the second and fifth transistors are coupled in common to the ninth transistor, and
wherein the third and sixth transistors are coupled in common to the tenth transistor.

14. The apparatus of claim 13, further comprising a voltage generator configured to generate the third signal having a fixed potential.

15. The apparatus of claim 14, further comprising:
an eleventh transistor outputting the second signal; and
a decoupling capacitor coupled to the eleventh transistor,
wherein the first and fourth transistors are configured to perform as a current mirror circuit such that the fourth transistor is configured to perform as an input transistor, and that the first transistor is configured to perform as an output transistor,
wherein the eleventh transistor has a gate electrode coupled to a connection node between the first transistor and the second transistor, and
wherein the output signal is fed back to the fifth and sixth transistors.

16. The apparatus of claim 15, further comprising first and second resistors coupled in series to the eleventh transistor,
wherein the second signal appears between the first resistor and the second resistor.

17. An apparatus comprising:
a current mirror circuit having an input node and an output node;
a current source circuit configured to provide the current mirror circuit with an operation current;
a first input circuit coupled between the input node of the current mirror circuit and the current source circuit; and
a second input circuit coupled between the output node of the current mirror circuit and the current source circuit,
wherein the first input circuit includes first and second transistors coupled in parallel and configured to be commonly controlled by a first signal,
wherein the second input circuit includes third and fourth transistors coupled in parallel and configured to be commonly controlled by a second signal,
wherein the first transistor is configured to be brought into an ON state when the first signal has a first level and brought into an OFF state when the first signal has a second level,
wherein the second transistor is configured to be brought into an ON state when the first signal has the second level and brought into an OFF state when the first signal has the first level,
wherein the third transistor is configured to be brought into an ON state when the second signal has the first level and brought into an OFF state when the second signal has the second level, and
wherein the fourth transistor is configured to be brought into an ON state when the second signal has the second level and brought into an OFF state when the second signal has the first level.

18. The apparatus of claim 17, wherein the current source circuit includes a fifth transistor,
wherein the first and second transistors are coupled between the input node of the current mirror circuit and the fifth transistor, and
wherein the third and fourth transistors are coupled between the output node of the current mirror circuit and the fifth transistor.

19. An apparatus comprising:
a current mirror circuit having an input node and an output node;
a current source circuit configured to provide the current mirror circuit with an operation current;
a first input circuit coupled between the output node of the current mirror circuit and the current source circuit; and
a second input circuit coupled between the input node of the current mirror circuit and the current source circuit,
wherein the first input circuit includes first and second transistors coupled in parallel and configured to be commonly controlled by a first signal,
wherein the second input circuit includes third and fourth transistors coupled in parallel and configured to be commonly controlled by a second signal,
wherein the first transistor is configured to be brought into an ON state when the first signal has a first level and brought into an OFF state when the first signal has a second level,
wherein the second transistor is configured to be brought into an ON state when the first signal has either the first or second level,
wherein the third transistor is configured to be brought into an ON state when the second signal has the first level and brought into an OFF state when the second signal has the second level, and
wherein the fourth transistor is configured to be brought into an ON state when the second signal has either the first or second level.

20. The apparatus of claim 19, wherein the current source circuit includes fifth and sixth transistors,
wherein the first transistor is coupled between the output node of the current mirror circuit and the fifth transistor,
wherein the second transistor is coupled between the output node of the current mirror circuit and the sixth transistor,
wherein the third transistor is coupled between the input node of the current mirror circuit and the fifth transistor, and
wherein the fourth transistor is coupled between the input node of the current mirror circuit and the sixth transistor.
